(19) United States
(12) Patent Application Publication
(10) Pub. No.: US 2006/0289058 A1
(43) Pub. Date: Dec. 28, 2006

(54) Photoconductive polymer

(75) Inventors: Peter John Skabara, Greater Manchester (GB); Rory Berridge, Nottingham (GB)

Correspondence Address: NIXON & VANDERHYE, PC, 901 NORTH GLEBE ROAD, 11TH FLOOR, ARLINGTON, VA, 22203, US

(73) Assignee: The University of Manchester, Manchester (GB)

(21) Appl. No.: 11/151,641

(22) Filed: Jun. 14, 2005

(51) Int. Cl. H01L 31/00

(52) U.S. Cl. 136/263

(57) ABSTRACT

A photoconductive polymer comprising hetrocyclic residues comprised of thiophene units fused to substituted or unsubstituted tetrathiafulvalene units, said thiophene units being conjugated to, and linked by, olefinic double bonds. Particularly preferred polymers are of the formula (I) as defined in the specification. The polymers of the invention may be used in photovoltaic devices, e.g. in the form of solar cells, batteries or transistors.

The present invention relates to a photoconductive polymer, the synthesis thereof and photovoltaic devices incorporating the polymer.

A characteristic of photoconductive polymers is that their electrical conductivity is increased when the polymer is illuminated with electromagnetic energy of the appropriate wavelength. This increase in conductivity is due to an electron being excited (by the energy provided by the electromagnetic radiation) from the valence band to the conduction band of the polymer. Applications for photoconductive polymers include photovoltaic devices such as solar cells, diodes, transistors, capacitors and batteries.

With particular regard to solar cells, photoconductive polymers have a number of advantages compared to silicon which is the photovoltaic material that is predominately used for such cells at the present time. In particular, photoconductive polymers tend to be cheaper, simpler to process and more flexible than silicon.

Ideally a photoconductive polymer is capable of absorbing at a wavelength above 700 nm, i.e. the “sweet spot” in the electromagnetic spectrum below which solar photon flux decreases. However, many photoconductive polymers that have absorption characteristics in the near i.r. are unstable and/or poorly soluble and this obviously represents a disadvantage compared to silicon.

A particular class of photoconductive polymers that have been investigated comprise a polythiophene backbone to which tetrathiafulvalene (ttf) units are attached, see for example Chem. Commun, 2000, 1005-1006 (Peter J Skabara et al.) and J. Mater. Chem. 2004, 14, 1964-1969 (Peter J Skabara et al).

The present invention relates to a development of electroconductive polymers based on a polythiophene backbone with attached tetrathiafulvalene units with a view to overcoming the above mentioned disadvantages of conventional photoconductive polymers.

It is broadest aspect, the present invention provides a photoconductive polymer comprising hetrocyclic residues comprised of thiophene units fused to substituted or unsubstituted tetrathiafulvalene units, said thiophene units being conjugated to, and linked by, olefinic double bonds.

According to a particularly preferred embodiment of the present invention, the photoconductive polymer is of the formula (I):

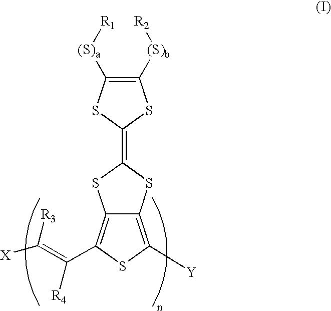

wherein

n is the degree of polymerisation,

a and b are independently 0 or 1,

X and Y are the same or different chain terminating residues,

R₁ and R₂ are the same or different and are selected from hydrogen and aliphatic and aromatic residues, or R₁ and R₂ together form a carbocyclic or heterocyclic ring, and

R₃ and R₄ are the same or different and are H or electron withdrawing groups.

It should be noted that no particular stereochemistry is implied for the olefinic double bond depicted in formula (I) above. Thus, adjacent thiophene residues (with fused ttf units) may be cis- or trans- to each other with respect to the double bond. Thus formula (I) is intended to cover both the cis- or trans-isomers. On photoexcitation, the quinoidal form is obtained and the heterocyclic moieties can rotate to give any of the two possible isomers on relaxation, the trans-isomer usually predominating.

We have found, and this forms the basis of the present invention, that the photoconductive polymers of the invention, and particular those of formula (I), are low band gap materials that are capable for absorbing electromagnetic radiation down to a wavelength of 850 nm. Examples of polymers of formula (I) have a band gap of 1.45 eV. Interestingly, the electron donating units in polymers of formula (I), are provided by the TTF entities (whereas this would normally be the conjugated backbone for a photovoltaic polymer) and the conjugated backbone is responsible for light absorption. Polymers in accordance with formula (I) are capable for providing two electrons from each repeating unit. Additionally, the polymers are stable under ambient conditions and are readily processable. All of these characteristics render the polymers suitable for use in photovoltaic devices.

The photoconductive polymers of the invention may, for example, be used in a solar cell. For this purpose, the photoconductive polymer may be admixed with an electron acceptor compound and the admixture provided between appropriate electrodes which function as anodes and cathodes. The anode may for example be aluminium and the cathode may for example be an ITO layer (e.g. on glass). The electron acceptor compound may be a fullerene or fullerene derivative and may for example be [6,6]-phenyl-C₆₁ butyric acid methyl ester. A further example of photovoltaic device in which the polymers of the invention may be employed is a battery based on a plastic capacitor. Such a battery may comprise a layer of the photoconductive polymer with a gel electrolyte provided between an anode and a cathode. A further example of photovoltaic device is a transistor comprised of a layer of the photoconductive polymer which is in contact with source and drain electrodes. Such a transistor will further comprise a gate electrode separated from the layer of photoconductive polymer by an insulator layer.

In the polymer of formula (I), R₁ and R₂ are the same or different and are selected from hydrogen and aliphatic and aromatic residues, or R₁ and R₂ may together form a carbocyclic or hetrocyclic ring. If R₁ and/or R₂ are aliphatic groups they will for preference be hydrocarbyl groups, e.g. straight or branched chain alkyl, alkenyl or alkynyl groups. Such groups will for preference have 1-12 carbon atoms, more preferably 4 to 8 carbon atoms.

If R₁ and/or R₂ are aromatic groups then they may be carboaromatic groups or heteroaromatic.

The nature of the R₁/R₂ groups will not affect the band gap of the polymer significantly and to that extent R₁ and R₂ may be selected from a wide range of groups as exemplified above. It is, however, possible to “tailor” other properties of the polymer by appropriate selection of the R₁/R₂ groups. Thus, for example the HOMO (Highest Occupied Molecular Orbital) of the polymer may be varied depending on whether the R₁/R₂ groups are electron donating or electron withdrawing. The HOMO of the polymer represents the oxidation potential thereof and thus it is possible to vary this potential by appropriate selection of the R₁/R₂ groups.

The nature of the R₁/R₂ groups will also determine the solubility of the polymer. Improved solubility will be obtained if at least one (and preferably both) of the R₁/R₂ groups are long chain alkyl groups or ethylene glycol groups. The solubility characteristics of the polymer will determine the ease with which it may be processed for particular applications. For example R₁/R₂ may be selected so that the polymer is soluble in organic solvents to allow production of a film of the polymer.

If the R₁/R₂ are aromatic then the polymer will display improved pi stacking which in turn has an influence on charge transport (enhanced charge transport is obtained if R₁ and R₂ are aromatic groups).

The R₃ and R₄ groups in the polymer of formula (I) may be hydrogen or may be electron withdrawing groups, e.g. cyano or fluorine.

Preferably both of a and b are 1.

For preference, the value of n is in the range 1-1000, more preferably 10-50.

By suitable choice of, particularly, R₁, R₂, R₃, R₄ and the value of n it is possible to produce a range of polymers which will have the required processability for production of, and photoconductive properties for use in, a range of photovoltaic devices.

In one preferred embodiment of polymer of formula (I), each of R₁ and R₂ are n-hexyl groups and R₃ and R₄ are each hydrogen. The presence of the n-hexyl groups (as examples of R₁ and R₂) ensures that the polymer is soluble in common-organic solvents and therefore readily processable into any particular form required for a photovoltaic device. Thus, for example, a film of the polymer may be produced by a conventional spin-coating technique.

Polymers of formula (I) may be produced by reacting a compound of formula (IV)

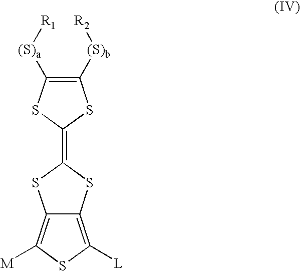

in which R₁₋₂, and a and b are as defined above and L and M are the same or different leaving groups with a compound of formula (V)

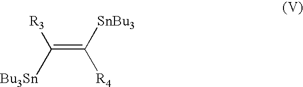

in which R₃₋₄ are as defined above.

The reaction to produce the polymer of formula (I) may be conducted in an organic solvent (e.g. toluene) under reflux in the presence of a polymerisation catalyst e.g. Pd (PPh₃)₄.

Typically the leaving groups L and M will both be halogen atoms, particularly bromine atoms.

Based on L and M both being halogen atoms, the synthetic procedure outlined above will lead to a polymer of formula (I) in which X is of the formula (II):

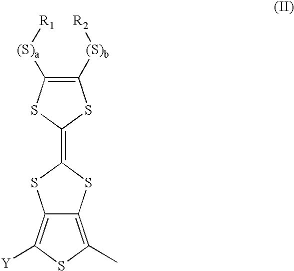

Thus for the case where R₁ and R₂ are n-hexyl groups, Y is halogen is X is defined above, the synthetic procedure leads to a polymer of the formula (III):

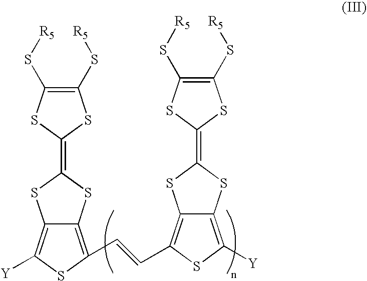

wherein each R₅ is an n-hexyl group and Y is a halogen atom.

For polymers of formula (I) in which the chain terminating group X is of formula (II) as shown above (in which Y is halogen) then the chain-terminating halogen atoms may be converted to aromatic groups, e.g. by Suzuki, Stille or Negishi Coupling Reactions.

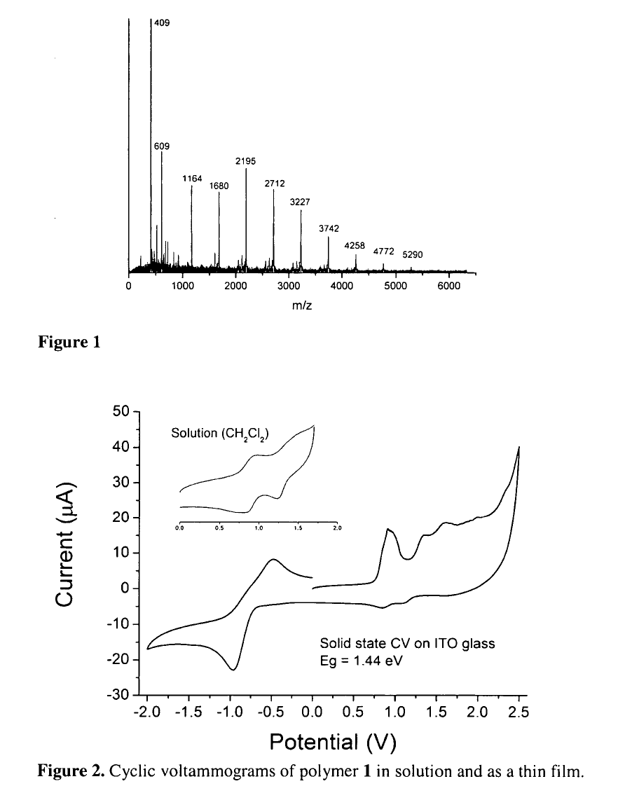

The invention is illustrated by the following non-limiting Example and the accompanying drawings in which FIGS. 1-9 illustrate the results of the Example and FIGS. 10-12 illustrate photovoltaic devices that may be constructed with the photoconducting polymer of the invention.

### EXAMPLE

The polymer (1) was prepared in accordance with Scheme 1 from the reaction of dibromo derivative (2)ⁱ with 1,2-bis(tributylstannyl)ethylene (3)ⁱⁱ in toluene with Pd(PPh₃)₄ as the catalyst. 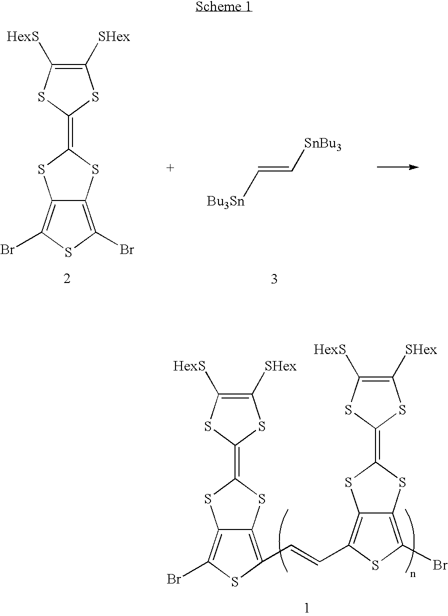
To 10 mL of freshly distilled anhydrous toluene under nitrogen atmosphere was added 0.54 g of 2 (0.825 mmol) and 0.50 g of 3 (0.825 mmol). The mixture was stirred at room temperature for 10 minutes to yield a yellow solution. Maintaining the inert atmosphere, 0.048 g of tetrakis(triphenylphosphine) palladium[0] (0.04125 mmol, 5 molar %) was added and the subsequent mixture refluxed for 18 hours to yield a purple/black solution. After cooling to room temperature the volume was reduced to ˜5 ml under vacuum and a large excess of methanol added (100 mL), precipitating a dark blue/black powder. Purification was achieved by soxhlet extraction with methanol, acetone and finally dichloromethane. The dichloromethane fraction (dark blue) was reduced in volume to ˜5 mL and added dropwise to 100 mL methanol to re-precipitate the product. Filtration and drying yielded 0.316 g of a dark blue powder. Polymer 1 was characterized by GPC against polystyrene standards in chloroform and the results indicated the presence of short chain polymers (Mₙ=3158, M_{w}=3750). The MALDI-TOF mass spectrum (see FIG. 1) shows major peaks with mass differences corresponding to the repeat unit (TTF-thiophene and vinylene units, 516 mu). The spectrum clearly shows that 1 is end-capped with TTF-thiophenes and that the terminal bromine groups are intact. These results are also supported by the ¹H NMR (CDCl₃) spectrum of 1, which confirms the absence of tributyl tin groups in the polymer. The highest mass peak in the MALDI spectrum (5290) equates to ten TTF-thiophene units in the PTV chain, which is somewhat higher than the polymer weight deduced from the GC results.

Thermogravimetric analysis was performed on polymer 1. Decomposition of 1 begins at 167° C., with an 8% weight loss by 251° C. Further, accelerated decomposition occurs after this point and an overall weight loss of 40% is achieved by 312° C.

Electrochemistry

The electrochemical behaviour of the polymer (1) has been studied by cyclic voltammetry in solution and as a thin film deposited on an ITO working electrode. The results are summarized in Table 1. The electroactivity of the monomers is centred within the TTF units: in fact, the redox potentials for polymer 1 are very close to those for the dibromo monomer 2.

TABLE 1
Electrochemical data for monomer and polymer.

| | E₁ₒₓ^{1/2} | E₂ₒₓ^{1/2} | | |
|---|---|---|---|---|
| | V vs. Fc/Fc⁺ | V vs. Fc/Fc⁺ | E_{red}^{1/2} | BE^{†} |
| 2 | +0.95 | +1.31 | | |
| 1 (solution) | +0.89 | +1.31 | | 2 |
| 1 (solid state) | +0.91^{irr} | +1.35^{irr} | −0.73^{q} (0.49 | 2 |
| | | | V difference) | |

DCM, 0.1 M Bu₄NPF₆, 100 mV s⁻¹;
^{†}bulk electrolysis: number of electrons removed per repeat unit at +1.4 V;
^{irr}irreversible peak;
^{q}quasi-reversible peak.

Electronic Absorption Studies

Absorption spectra for the polymer 1 and monomer 2 in solution and, for the polymer 1, in solid state form on ITO glass. The data is collated in Table 2. In the solid state, the longest wavelength absorption band for polymer 1 has an onset at 854 nm, which equates to a band gap of 1.45 eV.

TABLE 2
Electronic absorption data for polymer 1 and monomer 2.

| | | | Electronic | |
|---|---|---|---|---|
| | | | band gap in | Electroche |
| | Solution | Thin film | solid state | mical band |
| | λₘₐₓ (nm) | λₘₐₓ (nm) | (eV) | gap (eV) |
| 2 | 337 | — | — | — |
| 1 | 578 | 598 | 1.45 | 1.44 |

Solution state and solid state voltammograms for polymer 1 are shown in FIG. 2. Reversibility of the oxidation processes is greatly diminished in the solid state and, in this case, the difference between the onset of the first oxidation wave and that of the reduction wave gives the true electrochemical band gap. This change in electronic behavior could be due to significant interactions taking place in the solid state and we tentatively suggest that this could be due to intermolecular charge transfer between the polymer chains and the oxidized TTF unit.

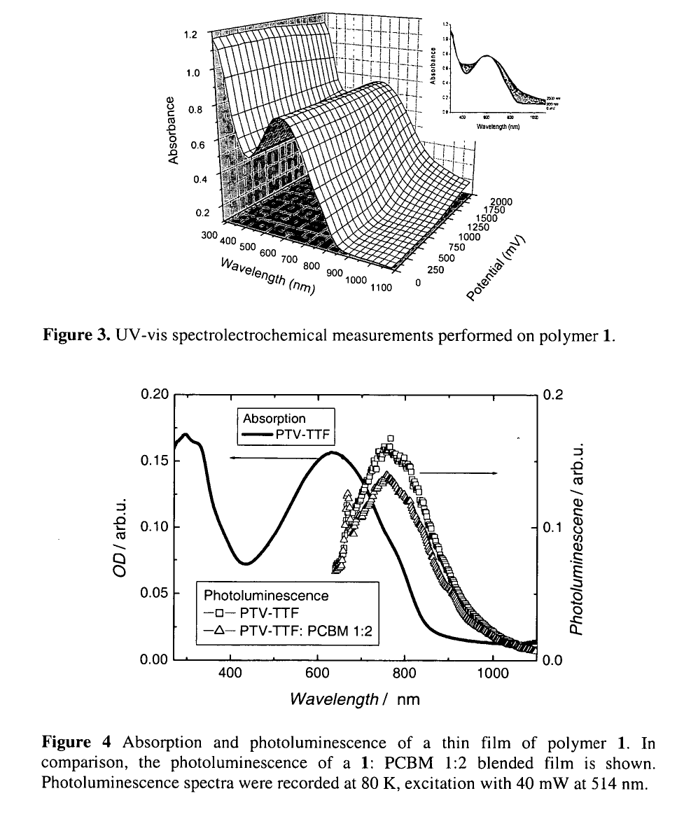

UV-vis spectroelectrochemical measurements were performed on thin films of polymer 1 spin-coated or electrodeposited onto ITO glass. All experiments were conducted in acetonitrile solution at a potential range which covered the neutral states of-the polymer and both oxidation processes observed in the cyclic voltammograms of the material. The results are depicted in FIG. 3. Previous spectroelectrochemical studies conducted on TTF and its derivatives^{iii,iv} have identified several unique absorption characteristics derived from the oxidized TTF units. The product from the first oxidation process, TTF^{·+}, usually gives rise to two new absorption bands (430 and 580 nm for TTF itself). These new peaks are often accompanied by a third band at ca. 800 nm, which can be assigned to an intermolecular charge-transfer process between TTF^{·+}dimers or as an additional feature of the cation radical species.^{V} Once the molecule is oxidized to the dication these peaks disappear and a new band emerges at lower wavelengths (390 nm for TTF²⁺).^{vi} In the spectrum of FIG. 3, the absorption peaks of polymer 1 extends to approximately 680-850 nm, which precludes the identification of the TTF dication and the two lowest wavelength absorption bands of the cation radical.

The spectroelectrochemistry is remarkably featureless, with only a small increase in absorbance within the shoulders of the main absorption peak centered at 598 nm. We expect the oxidation processes to derive from the TTF units, with some possible delocalization over the conjugated chain. However, it is quite astonishing that the π-π* band remains completely unchanged throughout the experiment, even up to +2.0 V, indicating that the conjugated chain is perfectly preserved and electrochemically inert.

Photoluminescence and Photoinduced Absorption Spectra of Polymer 1

Thienylene vinylene based oligomers^{vii,viii,ix,x} and polymers^{xi,xii} have been studied in the last few years as promising candidates for low band gap materials. Optical absorption onsets <1.5 eV have been reported for such material systems.^{xiii} The absorption characteristics of 1 are compared with the emission spectrum in FIG. 4 (excitation wavelength 514 nm). The main longest wavelength absorption peak shows a maximum around 630 nm and an onset around 850 nm. The photoluminescence is weak and shows a broad maximum at 800 nm and a relatively sharp peak at 670 nm. The origin of the 670 nm peak in the photoluminescence spectrum is unclear and the absorption and photoluminescence spectra are overlapping. A similar effect has been reported for poly-(2,5-thienylene vinylene) films.^{xiv} The photoluminescence of 1 is preserved in blends with [6,6]-phenyl-C₆₁ butyric acid methyl ester (PCBM).

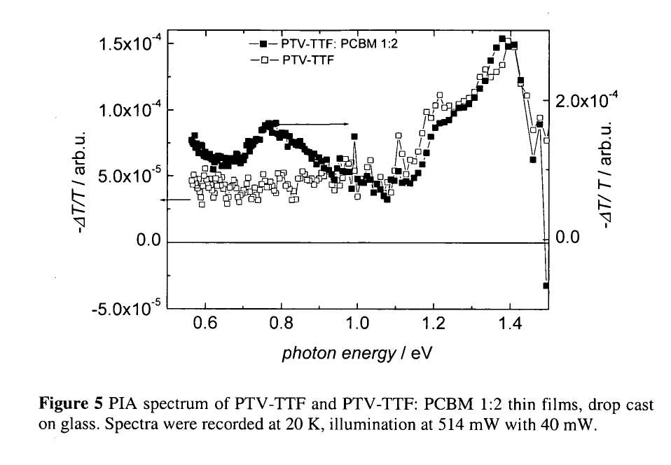

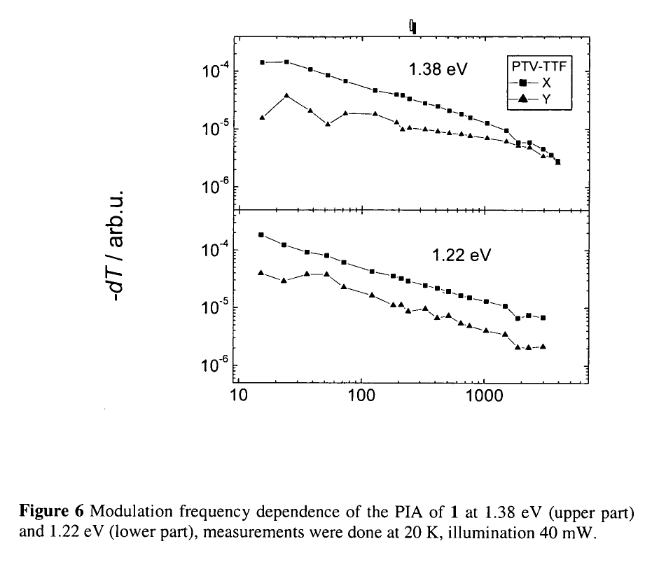

From the electrochemical measurements, the energy values for the HOMO and LUMO of polymer 1 are −5.24 eV and −3.78 eV, respectively. The LUMO of 1 shows only a small energy offset to the LUMO of PCBM (−3.75 eV)^{xv} and, from this point of view, the energetic possibility for photoinduced electron transfer from 1 to PCBM is unclear. The photoinduced absorption (PIA) spectrum of 1, see FIG. 5 shows a peak at 1.35 eV with a shoulder at 1.2 eV. In the near infrared region between 1.0 and 0.6 eV, a significant offset without any distinct feature is observed. The modulation frequency dependences of the PIA at 1.38 and 1.22 eV are weak and no crossing of the in and out-of-phase signals are observed (FIG. 6). This indicates relatively short lifetimes (τ<0.1 ms) with a broad inhomogeneous distribution. No model could be found to fit this modulation dependence satisfactorily. The PIA spectrum of a 1: PCBM blend film is shown in FIG. 5. The 1.4 eV PIA of the pristine polymer is preserved in the blend, but additionally, two new absorption peaks at 0.8 and <0.55 eV are observed.

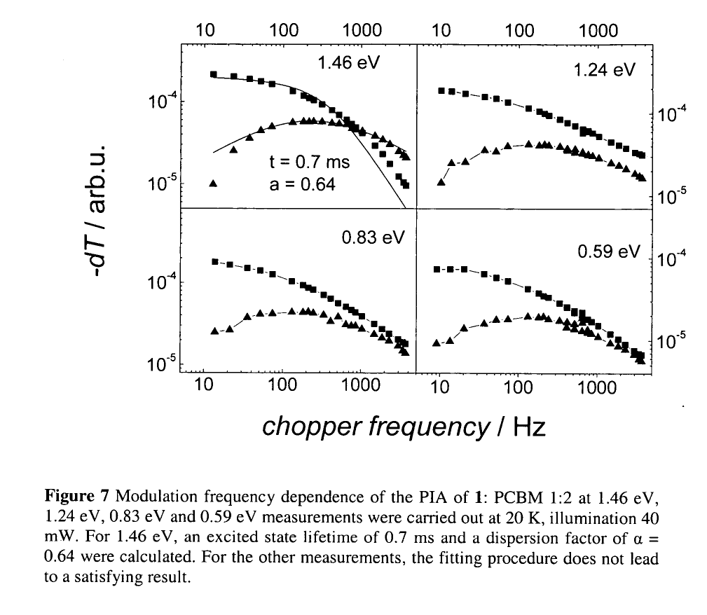

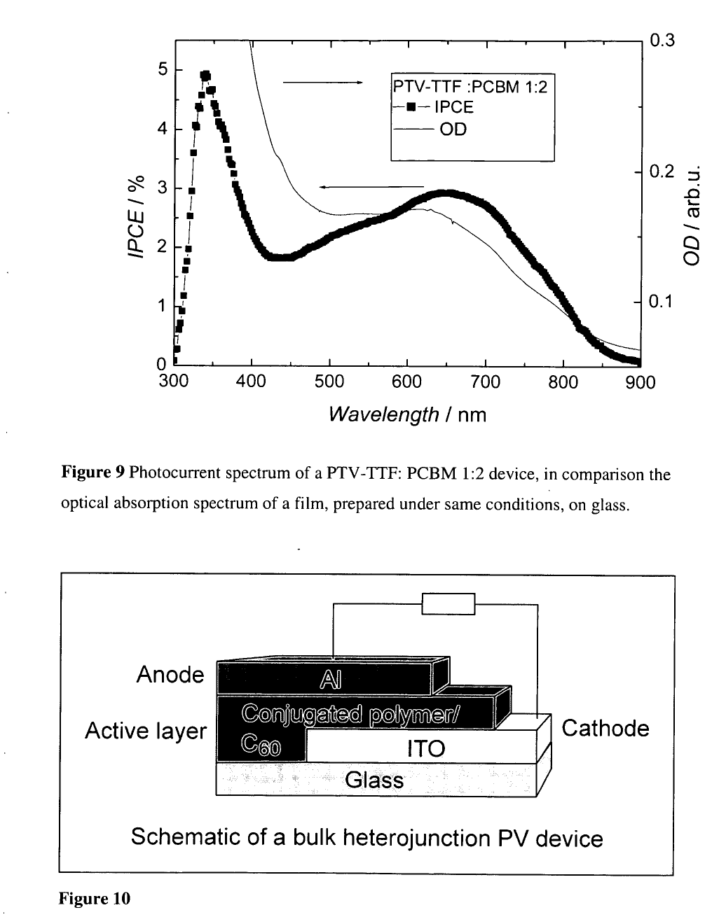

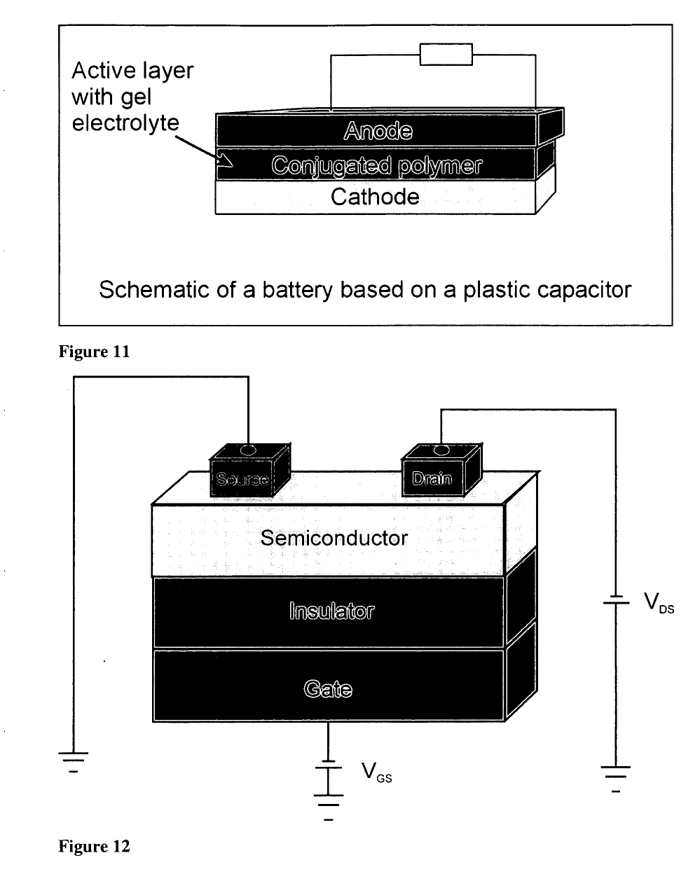

The modulation frequency dependences (FIG. 7), show the differences for the 1.4 eV band and the new absorptions at 0.8 and <0.55 eV. The peak at 1.46 eV could be fitted by the dispersive recombination model with a mean lifetime of τ=0.7 ms. The lifetime shows a broad distribution (α=0.64). The two low energy peaks show a weaker dependence on the modulation frequency, indicating shorter lifetimes. Their dependence could not be fitted satisfactorily. Excited state interactions between oligothienylenevinylenes and fulleropyrrolidines (MP-C₆₀) in solution have been investigated by Apperloo et al.^{xvi} The PIA spectra for 1 and the blend with PCBM are compared with spectra for hexyl-substituted dodeca(thienylenevinylene) (12TV): MP-C₆₀ mixed solution. The optical absorption of 12TV in CH₂CI₂ shows a maximum at 2.11 eV, compared with 2.06 eV for 1 in chlorobenzene solution. In the solid state, the absorption maximum is shifted to 1.96 eV. PIA of 12 TV and MP-C₆₀ in the non-polar solvent toluene shows a peak at 1.42 eV. This peak is assigned to a Tₗ→Tₙ absorption of triplet excited 12TV. In the more polar solvent o-dichlorobenzene, two additional peaks at 0.46 and 1.00 eV are observed in addition to the 1.42 eV peak. These two new absorptions are assigned to the 12TV radical cation. This assignment is confirmed by in-situ electrochemical absorption measurements.^{xvii} FIGS. 10-12 of the accompanying drawings are self-explanatory illustrations of various types of photovoltaic device in which photoconductive polymers of the invention may be incorporated. In FIGS. 9-12 the term “conjugated polymer” represents a conductive polymer in accordance with the invention. The device shown in FIG. 10 is suitable for use as a solar cell and comprises an admixture of the photoconductive polymer and a fullerene derivate (C₆₀) between aluminium and ITO electrodes. The device of FIG. 11 is suitable as a battery and comprises the photoconductive polymer in a gel electrolyte (to ensure relatively easy oxidation of the polymer). The device of FIG. 12 is a transistor with the photoconductive polymer being provided as the “semi-conductor” layer. Furthermore, for polythienylenevinylene polaron absorptions were determined by Lane et al. by Photoinduced Absorption Detected Magnetic Resonance at 1.1 eV and 0.4 eV.^{xviii} Apperloo et al. determined that the triplet and charge separated state of 12TV possess comparable energies. It is therefore assumed that the triplet state of 12TV and the charge separated state can be formed and observed simultaneously^{xix}. In the PIA for both materials, a peak at 1.4 eV is observed. This peak was assigned to a T₁→Tₙ absorption. Furthermore, the 0.8 eV and <0.55 eV peaks are comparable with the cation absorption of 12TV at 1 eV and 0.46 eV and therefore assigned to the polaron absorption of 1. Similar to the optical absorption, a redshift is observed for the positive polaron. In blends of 1 and PCBM, the coexistence of triplets and charge separated state is concluded. The quantum efficiency for the charge separation is unclear.

Photovoltaic Device Work from Polymer 1

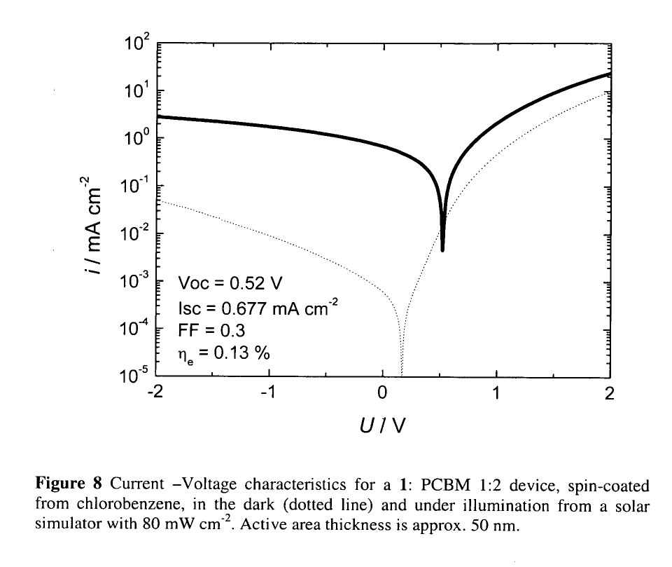

Polymer 1 shows non-favourable film forming properties, therefore no electro-optical characterization could be obtained. In combination with PCBM, thin films of sufficient quality can be spin cast from chlorobenzene solution. The I-V characteristics shows good diode behaviour with a rectification factor R(+/−2V)=250 (FIG. 8). Under illumination, a photovoltaic effect is observed with a power conversion efficiency of 0.13% under solar simulated light. This is comparable with literature values reported for polythienylene vinylene based bulk heterojunction devices.^{xx} The photocurrent spectrum (FIG. 9), shows peaks at 350 and 650 nm, corresponding to PCBM and 1 absorption, respectively. The onset for the photocurrent is around 850 nm, corresponding to the absorption onset of 1. As such, the optical response of the solar photovoltaic devices are improved to lower band gaps; however, the nanomorphology has to be engineered and the charge carrier mobility has to be improved to obtain higher current densities.

Conclusions

Polymer 1 is a low band gap, PTV-based material which is stable under ambient conditions and solution processable. In blends with PCBM, photoluminescence is not significantly affected, providing further evidence that charge transfer does not affect the electronic structure of the main chain. Blends of 1:PCBM deliver a photocurrent up to 850 nm, which represents the onset of the π-π* absorption band of the conjugated PTV chain. Since the electron donating sites within the structure of 1 originate from the TTF units, photoinduced electron transfer must involve the participation of the PTV chain and the TTF species in tandem. Spontaneous charge transfer between the TTFs and C₆₀ does not take place, because the HOMO-LUMO difference is significantly large. Photoexcitation of the polymer is expected to lead to the quinoidal state depicted in Scheme 1. For each 1,3-dithiole unit fused to the main chain, there is now a formal double bond within the ring. The ionisation potential for the TTF unit should be lowered in this structure, since the loss of an electron from the fused dithiole ring will be more favoured due to the generation of a 6π aromatic intermediate. It is feasible, therefore, that photoexcitation of the polymer initiates this process and fosters electron transfer from the TTF unit to the fullerene acceptor.

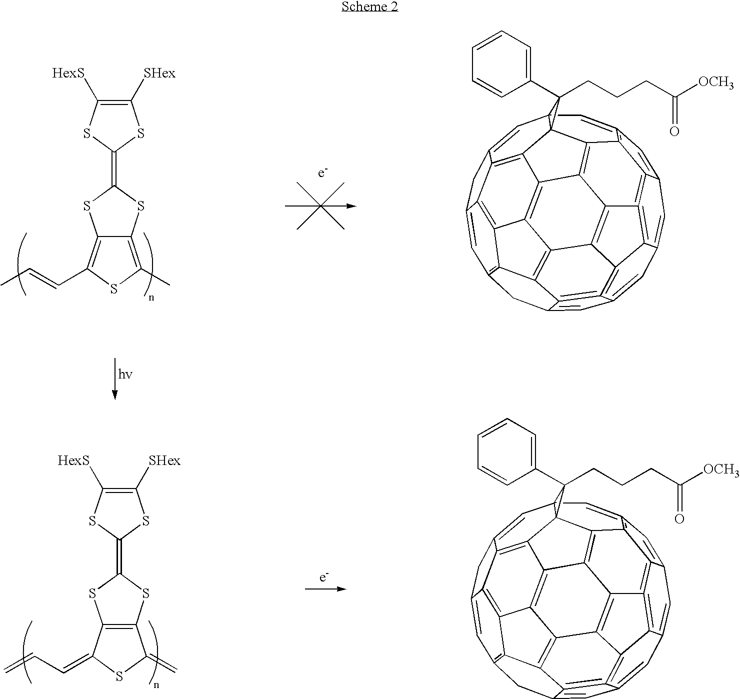

### REFERENCES

(ⁱ) P. J. Skabara, R. Berridge, E. J. L. McInnes, D. P. West, S. J. Coles, M. B. Hursthouse and K. Müllen, J. Mater. Chem., 2004, 14, 1964
(ⁱⁱ) Renaldo, A.; Labadie, J. W.; Stille, J. K., Org. Synth., 1989, 67, 86-97.
(ⁱⁱⁱ) J. B. Torrance, B. A. Scott, B. Welber, F. B. Kaufman and P. E. Seiden, Phys. Rev. B, 1979, 19, 730.
(^{iv}) F. B. Kaufman, A. H. Schroeder, E. M. Engler, S. R. Kramer and J. Q. Chambers, J. Am. Chem. Soc., 1980, 102, 483.
(^{v}) V. Khodorkovsky, L. Shapiro, P. Krief, A. Shames, G. Mabon, A. Gorgues and M. Giffard, Chem. Commun., 2001, 2736.
(^{vi}) L. Huchet, S. Akoudad, E. Levillain, J. Roncali, A. Emge and P. Bäuerle, J. Phys. Chem. B, 1998, 102, 7776
(^{vii}) Ono, N.; Okumura, H.; Murashima, T. Heteroatom Chemistry 2001, 12, 414
(^{viii}) Roncali, J.; Jestin, I.; Frère, P.; Levillain, E.; Stievenard, D. Synth. Met., 1999, 101, 667.
(^{ix}) Martineau, C.; Blanchard, P.; Rondeau, D.; Delaunay, J.; Roncali, J. Adv. Mater., 2002, 14, 283.
(^{x}) Rondeau, D.; Matrineau, C.; Blanchard, P.; Roncali, J. Journal of Mass Spectrometry 2002, 37, 1081.
(^{xi}) Xie, H.-Q. C.; Liu, M.; Guo, J. S. European Polymer Journal 1996,32, 1131.
(^{xii}) Guijiang, Z.; Junchao, L.; Cheng, Y. Synth. Met., 2003, 485, 135.
(^{xiii}) Jestin, I.; Frère, P.; Levillain, E.; Roncali, J. Adv. Mater. 1999, 11, 134.
(^{xiv}) Brassett, A. J.; Colaneri, N. F.; Bradley, D. D. C.; Lawrence, R. A.; Friend, R. H.; Murata, H.; Tokito, S.; Tsutsui, T.; Saito, S. Phys. Rev. B, 1990, 41, 10586.
(^{xv}) Brabec. C. J.; Sariciftci, N. S.; Hummelen, J. C.; Adv. Funct. Mater., 2001, 11, 15-26.
(^{xvi}) Apperloo, J. J.; Matrineau, C.; van Hal, P. A.; Roncali, J.; Janssen, R. A. J. J. Phys. Chem. B, 2002,106, 21
(^{xvii}) Apperloo, J. J.; Raimundo, J. M.; Frère, P.; Roncali, J.; Janssen, R. A. J. Chemistry, A European Journal, 2000, 6, 1698.
(^{xviii}) Lane, P. A.; Wei, X.; Vardeny, Z. V. Phys. Rev. Lett., 1996, 77, 1544.
(^{xix}) J. J Apperloo et al., Eur. J. Chem., 2000, 6, 1698
(^{xx}) Henckens, A.; Knipper, M.; Polec, I.; Manca, J.; Lutsen, L.; Vanderzande, D. Thin Solid Films 2004, 451, 572.

1. A photoconductive polymer comprising hetrocyclic residues comprised of thiophene units fused to substituted or unsubstituted tetrathiafulvalene units, said thiophene units being conjugated to, and linked by, olefinic double bonds.

2. A polymer as claimed in claim 1, said polymer being of the formula (I): 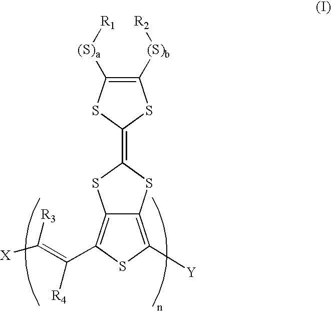
wherein
n is the degree of polymerisation,
a and b are independently 0 or 1,
X and Y are the same or different chain terminating residues,
R₁ and R₂ are the same or different and are selected from hydrogen and aliphatic and aromatic residues, or R₁ and R₂ together form a carbocyclic or heterocyclic ring, and
R₃ and R₄ are the same or different and are H or electron withdrawing groups.

3. A polymer as claimed in claim 2 wherein adjacent thiophene residues are trans- to each other with respect to the olefinic double bond.

4. A polymer as claimed in claim 2 wherein adjacent thiophene residues are cis- to each other with respect to the olefinic double bond.

5. A polymer as claimed in claim 2 wherein n is 1-1000.

6. A polymer as claimed in claim 5 wherein n is 10-50.

7. A polymer as claimed in claim 2 wherein a and b are each 1.

8. A polymer as claimed in claim 2 wherein R₁ and R₂ are the same or different and are alkyl groups having 1 to 12 carbon atoms.

9. A polymer as claimed in claim 8 wherein R₁ and R₂ are the same or different and are alkyl groups having 4 to 8 carbon atoms.

10. A polymer as claimed in claim 9 wherein R₁ and R₂ are each n-hexyl groups.

11. A polymer as claimed in claim 2 wherein R₃ and R₄ are each hydrogen.

12. A polymer as claimed in claim 2 wherein Y is a halogen atom and X is of the formula (II)

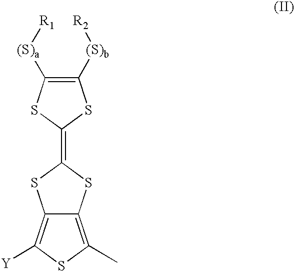

13. A polymer as claimed in claim 2 wherein X and Y are terminal aryl groups.

14. A polymer of formula (III) 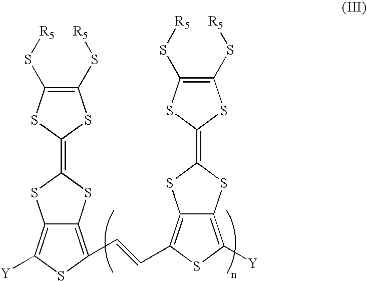
wherein each R₅ is an n-hexyl group and Y is a halogen atom.

15. A method of producing a polymer of the formula (I) as defined in claim 2, the method comprising reacting a compound of formula (IV) 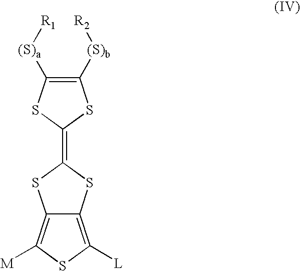
in which R₁₋₂, a and b are as defined in claim 2 and L and M are the same or different leaving groups with a compound of formula (V) 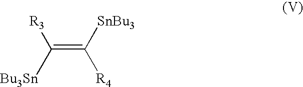
in which R₃₋₄ are as defined in claim 2.

16. A method as claimed in claim 15 conducted in the presence of Pd(PPh₃)₄ as catalyst.

17. A method as claimed in claim 15 wherein L and M are both halogen atoms.

18. A method as claimed in claim 17 wherein L and M are both bromine atoms.

19. A method as claimed in claim 18 further comprising the step of replacing the bromine atoms with aryl groups.

20. A photovoltaic device incorporating a photoconductive polymer as defined in claim 1.

21. A device as claimed in claim 20 in the form a solar cell comprising an anode, a cathode, and a blend of the polymer and an electron acceptor compound, said blend being provided between the anode and the cathode.

22. A device as claimed in claim 21 wherein the electron acceptor compound is selected from the group consisting of fullerenes and fullerene derivatives.

23. A device as claimed in claim 22 wherein the electron acceptor compound is [6,6]-phenyl-C₆₁ butyric acid methyl ester.

24. A device as claimed in claim 20 in the form of a battery comprising an anode, a cathode and a layer of the polymer with a gel electrolyte provided between the anode and the cathode.

25. A device as claimed in claim 20 in the form of a transistor comprised of a layer of the polymer in contact with source and drain electrodes, said transistor further comprising a gate electrode separated from the layer of the polymer by an insulator layer.

26. A composition comprising an admixture of a photoconductive polymer as defined in claim 1 and an electron acceptor compound.

27. A composition as claimed in claim 26 wherein the electron acceptor compound is selected from the group consisting of fullerenes and fullerene derivatives.

28. A composition as claimed in claim 27 wherein the electron acceptor compound is [6,6]-phenyl-C₆₁ butyric acid methyl ester.
